(19) United States
(12) Patent Application Publication
(10) Pub. No.: US 2009/0159913 A1
(43) Pub. Date: Jun. 25, 2009

(54) LIGHT-EMITTING DIODE

(75) Inventors: CHUN-WEI WANG, Chu-Nan (TW); HUNG-KUANG HSU, Chu-Nan (TW)

Correspondence Address: PCE INDUSTRY, INC.;ATT. Steven Reiss, 458 E. LAMBERT ROAD, FULLERTON, CA, 92835, US

(73) Assignee: FOXSEMICON INTEGRATED TECHNOLOGY, INC., Chu-Nan (TW)

(21) Appl. No.: 12/202,560

(22) Filed: Sep. 2, 2008

(30) Foreign Application Priority Data
Dec. 21, 2007 (CN) 200710203324.5

(51) Int. Cl. H01L 33/00

(52) U.S. Cl. 257/98; 257/E33.058

(57) ABSTRACT

An LED includes an LED chip having a first electrode and a second electrode, a first electrically conductive block and a second electrically conductive block insulated from the first electrically conductive block, a cavity defined in the first electrically conductive block configured for accommodating the LED chip, and a light pervious encapsulation covering the LED chip, the first electrically conductive block and the second electrically conductive block. The first electrically conductive block is electrically connected to the first electrode, and the second electrically conductive block is electrically connected to the second electrode.

### CROSS REFERENCE TO RELATED APPLICATION

This application is related to commonly-assigned copending application Ser. No. 12/168,783, entitled “LIGHT EMITTING DIODE WITH AUXILIARY ELECTRIC COMPONENT” (attorney docket number US16405). Disclosures of the above-identified application are incorporated herein by reference.

### BACKGROUND

1. Field of the Invention

The present invention relates generally to light-emitting devices and more particularly to a light-emitting diode (LED).

2. Description of Related Art

Generally, an LED includes a substrate, an LED chip disposed on the substrate, and a light pervious encapsulation covering the LED chip. The LED chip emits light therefrom, and then the light passes through the light pervious encapsulation to illuminate. Usually, a bowl or cup shaped space is defined in the substrate for receiving the LED chip. An intensity distribution of the LED can be adjusted according to the design of bowl or cup shaped space. The substrate is a silicon substrate coated with a metal layer for electrically connecting to LED chip. However, the coefficient of thermal expansion of the silicon substrate will be different from that of the metal layer, so that cracks are easier to occur in the substrate when the external temperature varies. As a result, moisture can penetrate the cracks.

Therefore, what is needed, is a light-emitting diode to overcome the above-described deficiencies.

### SUMMARY

An LED includes an LED chip having a first electrode and a second electrode, a first electrically conductive block, and a second electrically conductive block insulated from the first electrically conductive block. A cavity is defined in the first electrically conductive block configured for accommodating the LED chip, and a light pervious encapsulation covering the LED chip, the first electrically conductive block, and the second electrically conductive block. The first electrically conductive block is electrically connected to the first electrode, and the second electrically conductive block is electrically connected to the second electrode.

### BRIEF DESCRIPTION OF THE DRAWINGS

Many aspects of the present light-emitting diode can be better understood with reference to the following drawing. The components in the drawing are not necessarily drawn to scale, the emphasis instead being placed upon clearly illustrating the principles of the present light-emitting diode. Moreover, in the drawing like reference numerals designate corresponding parts throughout.

FIG. 1 is a schematic, cross-sectional view of a light-emitting diode in accordance with a first embodiment.

FIG. 2 is a bottom view of the light-emitting diode in FIG. 1.

FIG. 3 is a schematic view of the light-emitting diode in FIG. 1 and a circuit board configured for supporting the light-emitting diode.

FIG. 4 is a schematic, cross-sectional view of a light-emitting diode in accordance with a second embodiment.

### DETAILED DESCRIPTION

Reference will now be made to the drawings to describe in detail the preferred embodiments of the present light-emitting diode.

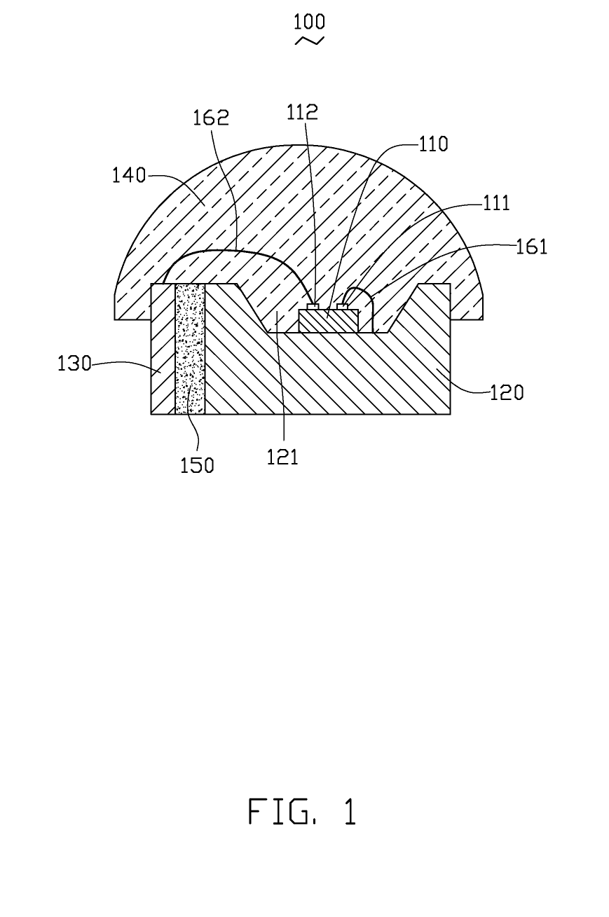

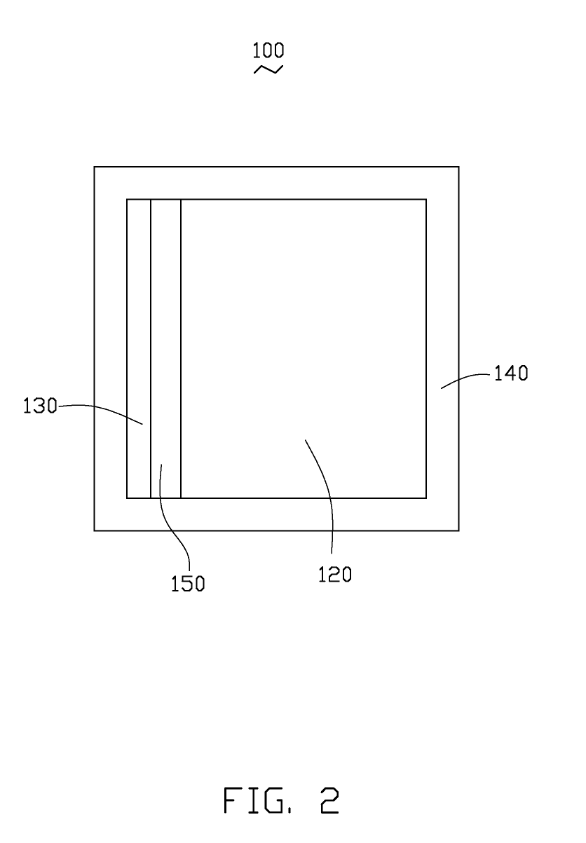

Referring to FIGS. 1 and 2, an LED 100 according to a first embodiment is shown. The LED 100 includes an LED chip 110, a first electrically conductive block 120, a second electrically conductive block 130, and a light pervious encapsulation 140.

The LED chip 110 includes a first electrode 111 and a second electrode 112. When a current is applied to the first electrode 111 and the second electrode 112, the LED chip 110 can emit light.

The first electrically conductive block 120 is block shaped. A bowl-shaped cavity 121 configured for accommodating the LED chip 110 is defined in the first electrically conductive block 112. The first electrode 111 is electrically connected to the first electrically conductive block 120. In the present embodiment, the first electrode 111 is connected to the first electrically conductive block 120 via a lead wire 161. The first electrically conductive block 120 can be made of alumina or copper. A reflective layer (not shown) can be coated on the inner surface of the bowl-shaped cavity 121, configured for reflecting the light emitted from the LED chip. The LED chip 110 can be adhesively mounted on the bottom surface of the bowl-shaped cavity 121.

The second electrically conductive block 130 is block shaped. The second electrically conductive block 130 is insulated from the first electrically conductive block 120. In the present embodiment, an insulating tape 150 is set between the first electrically conductive block 120 and the second electrically conductive block 130, thereby insulating the first electrically conductive block 120 from the second electrically conductive block 130. The insulating tape 150 is made of a plastic material. The second electrically conductive block 130 is electrically connected to the second electrode 112. In the present embodiment, the second electrode 112 is connected to the second electrically conductive block 130 via a lead wire 162. The cross section of the second electrically conductive block 130 can be in other shapes such as rectangle, square, triangle, circle etc. The second electrically conductive block 130 can be made of copper or alumina.

The encapsulation 140 is disposed on the first electrically conductive block 120 and the second electrically conductive block 130, and covers the LED chip 110. The encapsulation 140 is configured for converging light emitted from the LED chip 110, thus adjusting an illuminating scope of the LED 100. Meanwhile, converging would focus the light thus increasing intensity. In addition, the encapsulation 140 protects the LED chip 110 from contaminants. The encapsulation 140 can be made of a light-permeable material including but not limited to cyclic olefin copolymer (COC), epoxy, silicone, polymethylmethacrolate (PMMA), polycarbonate (PC), PC and/or PMMA, and polyetherimide (PIE). The encapsulation 140 can be hemisphere-shaped. The encapsulation 140 also can be other shapes known in the art having light gathering function such as a cone-shaped lens. It is understood that fluorescent material can be doped into the encapsulation 140 to transform light emitted from the LED chip 110 into the light of a desirable color.

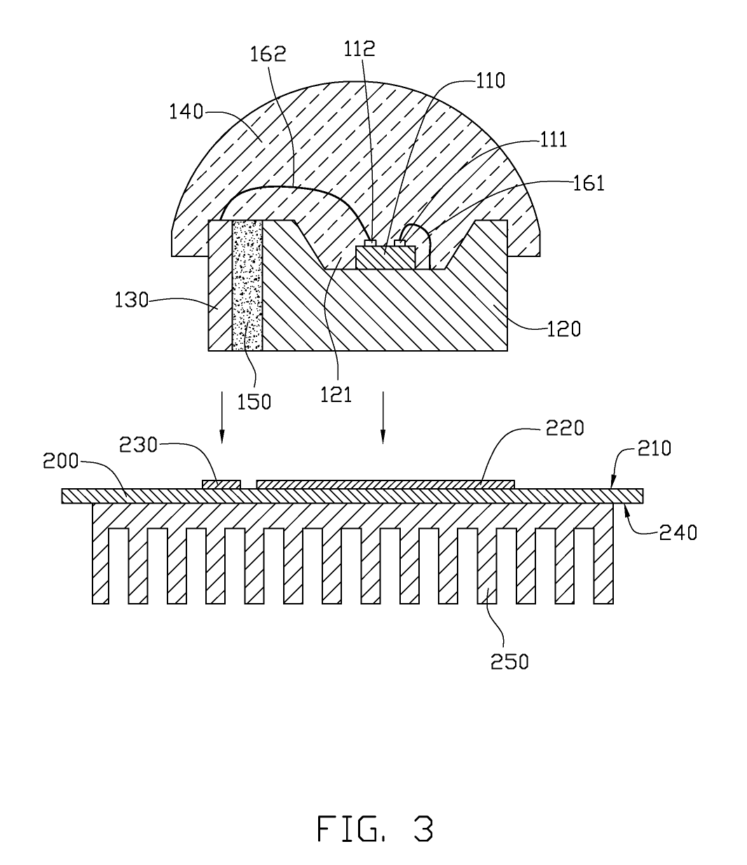

Referring to FIG. 3, the first and second electrically conductive blocks 120, 130 can be mounted on a circuit board 200 using surface mount technology (SMT). The circuit board 200 includes a first surface 210 and an opposite second surface 240. In the present embodiment, a first conducting resin 220 is coated on the first surface 210 corresponding to the first electrically conductive block 120. A second conducting resin 230 is coated on the first surface 210 corresponding to the second electrically conductive block 130. The first and second electrically conductive blocks 120, 130 are respectively disposed on the first and second conducting resins 220, 230. The first and second conducting resins 220, 230 can be tin creams. In order to dissipate heat more efficiently, the LED 100 can further comprise a heat sink 250 attached to the second surface 240.

Comparing with the bend electrodes of the conventional LED, the stress distribution of the first electrically conductive block 120 and the second electrically conductive block 130 is more uniform, and the cost of the electrodes will be decreased. The LED chip 110 can be directly mounted on the first electrically conductive block 120, to dissipate heat more efficiently. In addition, because the first electrically conductive block 120 is an integral body made of a single material, the first electrically conductive block 120 will not crack due to thermal expansion, and moisture cannot penetrate the LED chip 110.

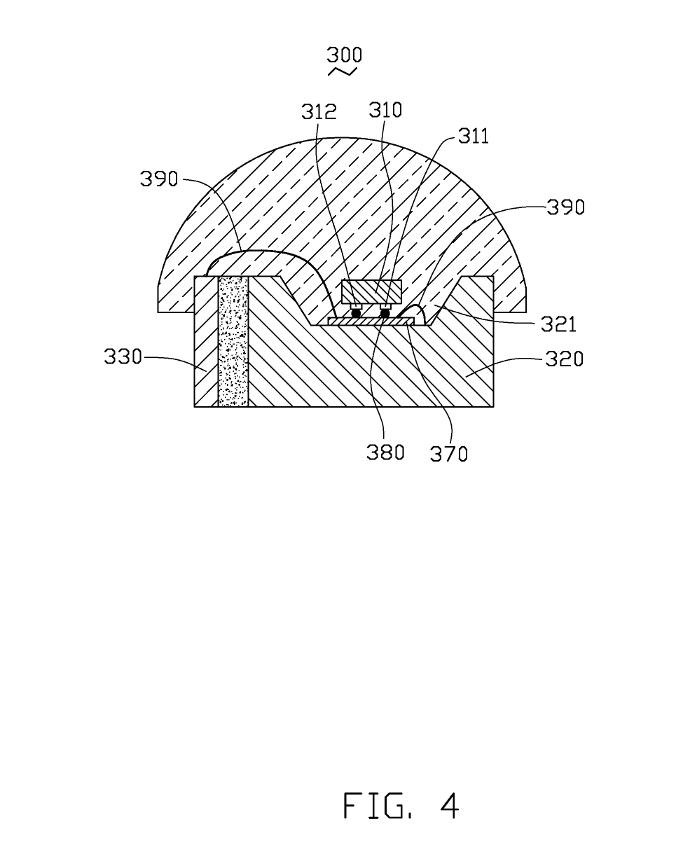

Referring to FIG. 4, an LED 300 according to a second embodiment is shown. The structure of the LED 300 is similar to that of the LED 100 in the first embodiment. The difference is that the LED chip 310 is mounted on the bottom surface of the bowl-shaped cavity 321 using a flip chip technique. More explicitly, the LED 300 includes an insulating substrate 370 with a circuit (not shown) formed thereon. The first electrode 311 and the second electrode 312 are electrically connected to the circuit of the insulating substrate 370 via metal balls 380, such as tin balls. The insulating substrate 370 is electrically connected to the first and second electrically conductive blocks 320, 330 via lead wires 390. The insulating substrate 370 is made of an insulating material, such as silicon, alumina nitride, beryllium oxide, silicon oxide, diamond, diamond like carbon, etc.

While the present invention has been described as having preferred or exemplary embodiments, the embodiments can be further modified within the spirit and scope of this disclosure. This application is therefore intended to cover any variations, uses, or adaptations of the embodiments using the general principles of the invention as claimed. Further, this application is intended to cover such departures from the present disclosure as come within known or customary practice in the art to which the invention pertains and which fall within the limits of the appended claims or equivalents thereof.

What is claimed is:

1. An LED comprising:
an LED chip having a first electrode and a second electrode,
a first electrically conductive block and a second electrically conductive block insulated from the first electrically conductive block, the first electrically conductive block being electrically connected to the first electrode, the second electrically conductive block being electrically connected to the second electrode, the first electrically conductive block having a recess defined therein, the LED chip received in the recess, and
a light pervious encapsulation member covering the LED chip, the first electrically conductive block and the second electrically conductive block.

2. The LED of claim 1, further comprising an insulating layer sandwiched between the first electrically conductive block and the second electrically conductive block.

3. The LED of claim 1, wherein the insulating layer is comprised of a plastic material.

4. The LED of claim 1, further comprising a first lead wire and a second lead wire, wherein the first electrically conductive block is electrically connected to the first electrode via the first lead wire, and the second electrically conductive block is electrically connected to the second electrode via the second lead wire.

5. The LED of claim 1, further comprising a circuit board, the first electrically conductive block and the second electrically conductive block being mounted on the circuit board.

6. The LED of claim 1 wherein the recess is bowl or cup shaped.

7. The LED of claim 1, further comprising a reflective layer formed on an inner surface of the recess.

8. The LED of claim 1, wherein the LED chip is adhesively mounted in the recess.

9. The LED of claim 1, wherein the LED chip is mounted in the recess using a flip chip technique.

10. The LED of claim 1, wherein the first electrically conductive block is a unitary body made of a single material.

11. The LED of claim 1, wherein the second electrically conductive block is a unitary body made of a single material.
